(19) United States
(12) Patent Application Publication
(10) Pub. No.: US 2016/0033561 A1
(43) Pub. Date: Feb. 4, 2016

(54) MODULAR METERING SYSTEM

(71) Applicant: Northern Design (Electronics) Limited, Bradford (GB)

(72) Inventors: Ian Sykes, Bradford (GB); Paul Clay, Bradford (GB); Julia Szajdzicka, Bradford (GB)

(21) Appl. No.: 14/881,898

(22) Filed: Oct. 13, 2015

Related U.S. Application Data
(63) Continuation of application No. 13/882,607, filed on Aug. 7, 2013, now abandoned.

(30) Foreign Application Priority Data
Nov. 1, 2010 (GB) 1018456.2
Dec. 31, 2010 (GB) 1022118.2

(51) Int. Cl. G01R 21/00

(52) U.S. Cl. CPC G01R 21/007

(57) ABSTRACT

A modular metering unit, shown generally at 10, comprises a master module 12, slave modules 14a to 14f, and a communications module 16. Together the modules 12, 14 and 16 make up a modular metering unit for metering electricity from plural loads (not shown) such as, in the case of a large food retail premises, chill or freeze display cabinets. Each of the slave modules includes electricity meters for measuring electricity supplied to a load. The loads may be located remotely from the metering unit and each one has a current detector that feeds a low-voltage signal back to the meter via a cable (not shown). The slave modules are connected to one another and to the master module by an internal bus through which data and power are carried between the modules.

The present invention relates to a system for metering. The invention is concerned particularly, although not exclusively, with a modular apparatus for metering energy.

Currently in domestic and commercial premises electricity, gas, water and air quality/usage, for example, are monitored using separate stand-alone meters. Particularly in commercial premises the electricity usage of several devices or appliances, hereinafter referred to generally as “loads”, is often monitored using separate meters for each load. In such cases, in order to derive valuable data about the energy usage of each load it is necessary to collate metered values manually, and subsequently enter the data manually on a computer for processing.

More sophisticated electricity meters are configured to send data automatically to a data logging device which may be local, or may be reached via a communications device, for example over the telephone line, or the internet.

A previously considered example of electricity meter brings together a fixed number of metering units and combines them in a unitary housing, together with a common visual display and processing means to manipulate and present the data collected by the individual metering units. Cables are used to carry the measurement signals from current detectors located locally at each load. The combined multi-meter load is particularly suited to modern premises in which the electrical supply enters the building at a single location, and is controlled from a single control panel.

Whilst the combined meter units of the prior system allow for data to be obtained and handled, and if necessary transmitted to a remote host, more easily than separate meters, the apparatus is typically supplied as a unit of fixed size, with a fixed number of meter units (usually twelve). When the premises have more loads than can be accommodated on a single multi-meter device it is necessary to install second or further devices, with the number of meter units increasing in multiples of twelve. This can often lead to an installation having many more meters than is necessary for the number of loads, leaving many meter units redundant. Such an inflexible system can therefore be needlessly expensive.

Furthermore, even if there is no, or little, redundancy the system may be unable to accommodate an expansion in the number of loads without requiring considerable further installation work.

Commercial organisations require increasingly large amounts of information about their energy usage in order to assist in the management of costs. Businesses are also seeking to monitor a growing number of different parameters, such as for example water usage, air quality/usage and footfall. Currently the metering or monitoring of electricity, gas, water, air quality and footfall is handled by a diverse array of equipment, and the collection, transmission and presentation of the information is a complex task. In order to capture, where necessary convert or standardise, and then log/transfer the data it is usually necessary to install specifically designed data processing apparatus in the premises. Such apparatus is usually expensive and often lacks versatility, so that it cannot always accommodate a request for a change in the type of information that is to be gathered.

Preferred embodiments of the present invention aim to address at least some of the aforementioned shortcomings in the prior systems.

The present invention is defined in the attached independent claims, to which reference should now be made. Further, preferred features may be found in the sub-claims appended thereto.

According to one aspect of the invention there is provided a modular metering system comprising a master module and at least one slave module arranged to measure a parameter, the master module being arranged to communicate electronically with the at least one slave module.

Preferably the system includes a plurality of slave modules and preferably at least one of the slave modules comprises an energy meter which may be an electricity meter. The system may be provided with a communications bus through which the master module may communicate with the, or each, slave module. Alternatively or in addition the system may include means for wireless communication between the master module and the, or each, slave module.

The system may include a communications module arranged to facilitate communication between the master module and a remote host.

The slave modules are preferably arranged for releasable physical engagement with the master module and/or other slave modules. In a preferred arrangement the physical engagement of modules automatically connects a data and/or power bus between them.

The master module is preferably arranged to poll the, or each, slave module. The polling of the, or each, slave module may be sequential. The slave modules may include a memory, which memory may be arranged to store data including calibration data.

In a preferred arrangement the master module includes a display, which display may be arranged to present information relating to one or more of the slave modules. The display may be controllable so as to allow a user to select the slave module from which information is to be presented. The master module preferably includes a user interface which may comprise an input device, such as a key pad.

Preferably the master module is arranged to calibrate the, or each, slave module. The master module may be arranged to calibrate a number of slave modules substantially simultaneously. The master module may also comprise power supply means for the slave modules, which power supply means may comprise an auxiliary power supply for the slave modules.

The master module may comprise electronic processing means and/or electronic memory means. The, or each, slave module may comprise electronic processing means and or electronic memory means.

In one preferred arrangement the master unit comprises a data logging means.

The system may include a plurality of electricity meters.

Preferably the system includes one or more slave modules comprising at least one three-phase electricity meter and/or three single-phase electricity meters.

The system may include slave modules arranged to monitor and/or meter parameters including at least one of electricity usage, gas usage, water usage, water quality, steam usage, air quality, air usage and entry/exit by persons through a door.

The invention also includes a method of energy management, comprising measuring and/or monitoring plural parameters using meter and/or monitor slave modules connected to a master module in a system according to any statement herein.

A preferred embodiment of the present invention will now be described by way of example only, with reference to the accompanying diagrammatic drawings in which:

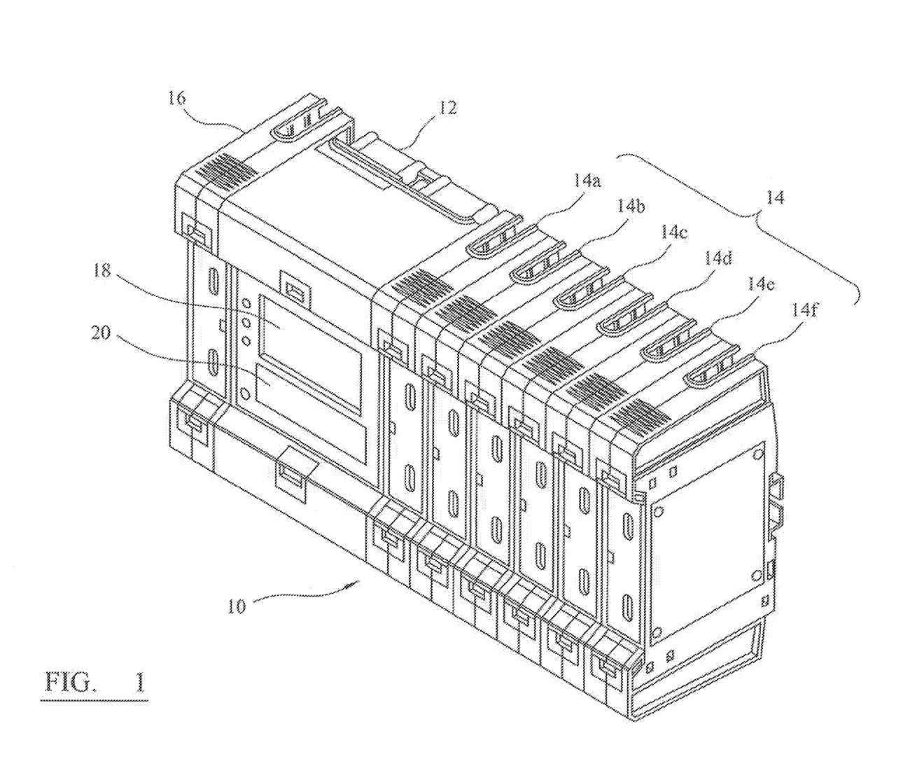

FIG. 1 is a schematic perspective view of a modular metering unit according to an embodiment of the invention;

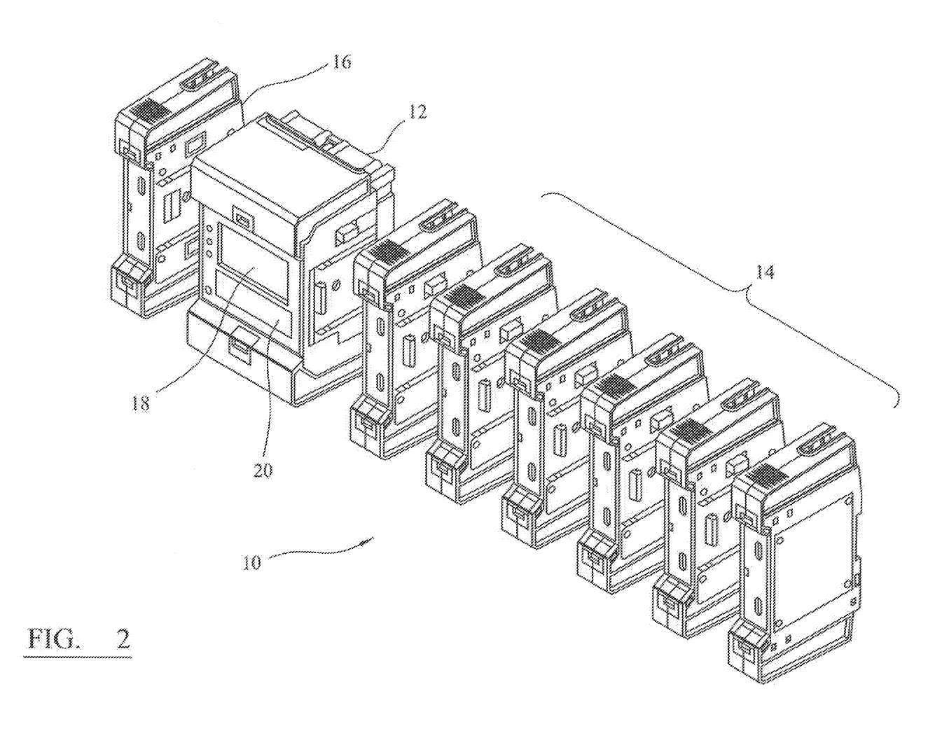

FIG. 2 shows the unit of FIG. 1 in partly exploded view; and

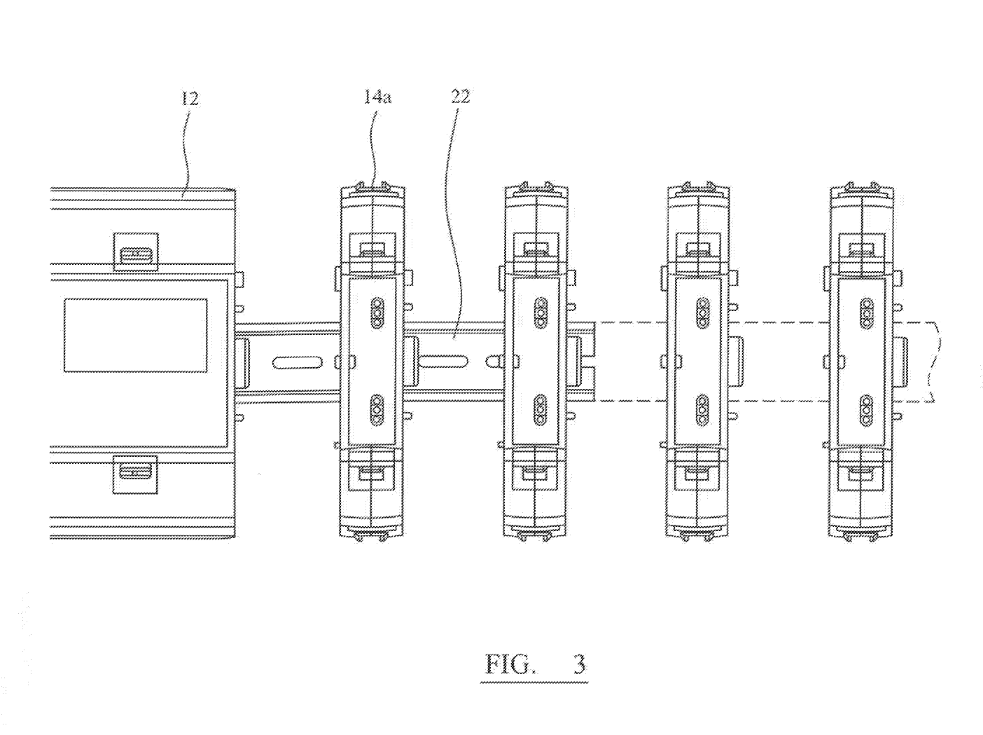

FIG. 3 is a schematic front view of part of the unit of FIGS. 1 and 2.

Referring to FIGS. 1 and 2 these show a modular metering unit generally at 10, comprising a master module 12, slave modules 14a to 14f, and a communications module 16. Together the modules 12, 14 and 16 make up a modular metering unit for metering electricity from plural loads (not shown) such as, in the case of a large food retail premises, chill or freeze display cabinets.

Each of the slave modules includes electricity meters for measuring electricity supplied to a load. The loads may be located remotely from the metering unit and each one has a current detector that feeds a low-voltage signal back to the meter via a cable (not shown).

The slave modules are connected to one another and to the master module by an internal bus through which data and power are carried between the modules.

The master module 12 comprises the hub of the system and communicates on a bespoke internal bus with the slave modules to interface/measure/collect/detect/monitor data relevant to an individual site/application. The master module is arranged to periodically pull data from each slave making it available to a user as though sourced from a single device. An LCD display unit 18 presents the data to a user. The master module also houses a 32-bit microprocessor (not shown) which, with custom firmware, is used to manipulate the data gathered from the slave modules making the data ready for external systems. Concentrating data in this way reduces the time and resource required for external systems to collect and manipulate a range of energy management data.

The display unit 18 can be optionally supplied as a data logger with a built-in real-time clock/calendar. This hardware/software option allows concentrated data from the slave modules 14 to be periodically stored in an internal database which is secure in the event of power failure to the system. Time-stamped logged data may be read remotely by an external energy management system or sent to a remote website for analysis. Secure local storage is the preferred approach for a number of applications such as sub-tenant billing and energy profiling, for example.

The master module 12 also includes an overlay keypad 20, with membrane keys which, together with the display 18, provide a versatile, single-user interface. The user selects a window for each of the slave modules 14 using the keypad 20 thus removing the need for multiple displays. This single user interface also allows setup/configuration of each slave, in addition to viewing its data.

The master module 12 acts as the main auxiliary power supply for the entire system. Mains voltage is connected to the master module where it is isolated and converted to a low level dc supply which is made available to the slave modules on the internal interconnecting bus.

In one embodiment high voltage measurement inputs are also connected at the master module, where they are attenuated and made available to any of the slave modules 14 via the internal interconnecting bus. This single connection point for voltage significantly reduces site wiring of the built system when multiple loads are measured.

The firmware in the master module may readily be upgraded in the field to take account of new developments in slave modules, thus making the system future proof.

In the embodiment shown each of the slave modules 14 comprises two, independent, multi-function, electricity meters. These meters measure three phase current via a range of external transducers located at the load, which transducers are selected to suit nominal currents, for example in the range of 5 A to 25,000 A. Each external transducer provides a safe signal at the measured point which is fed back to the metering system on a pair of wires. Firmware in the individual slave module linearises the measured current and corrects for inherent phase angle and gain errors making the overall system very accurate. The calibrated current signals are combined with the 3-phase voltages, fed from the master module on the interconnecting bus. The resultant data is manipulated to provide measured parameters of volts, amps, kw and frequency and many derived values such as power factor, kVA, kvar, energy, harmonics, THD, max/min and demand values. A complete set of electricity parameters are made available on request (each second) to the display unit 18.

In one embodiment calibration and user configuration settings in a dual-meter slave are provided by the master module/central display unit. This allows a number of metering slaves to be calibrated simultaneously, thereby reducing manufacturing costs significantly. This setup data is stored in the slave and secured during power failure so that slaves can be moved from engagement with one master module to another, allowing each slave to be completely autonomous. A system using master and slave serial numbers/slave types provides a method of tracking slaves, thereby easily facilitating in-system upgrades and maintenance.

Each metering element in the dual slave can be independently configured, by the master module, to measure a 3-phase load or 3 separate single phase loads. This provides flexibility in measuring a combination of load types in a single mains distribution board.

The communications module 16 is connected to the left of the central display unit allowing connection of the modular system as a whole to a host, such as a building energy management system (not shown).

Data from the communication module is transferred to/from the master module via a second, independent internal data/power supply bus. A range of communications modules may be supplied, some of which contain additional processing power to provide high speed access to the data in the master module and therefore to the slave module data. Communications modules may be provided for connection to remote hosts via GPRS (mobile phone), Wi-Fi, Zigbee, Ethernet etc.

FIG. 3 shows part of the unit 10 in exploded view. The individual modules connect together by a releasable snap-fit engagement and each clips on, at its rear, to a DIN rail 22.

Whilst the embodiment shown in the drawings comprises six slave modules, the unit can have more modules or fewer in order to accommodate the specific load requirements of the installation. Since new modules can readily be connected, the system may be expanded as more loads are added. As the modules are snapped together they become physically engaged and at the same time the internal power/data bus becomes connected.

Furthermore, the inherent flexibility of the system allows a range of slave modules of different kinds to function as elements of a complete energy management solution. In embodiments of the present invention the system may combine a number of multi-function electricity meters with other elements of a complete energy management system in a single compact unit. Again, each slave device communicates with the master module on a standard communication/power bus.

Other modular slaves which may be provided include pulse-input collectors, which allow other utility meters such as gas, water, steam and air meters, for example, to feed data into the master display unit. Other energy management parameters may be introduced to the system by using an analogue input module, allowing other quantities/qualities to be metered and/or monitored, via external transducers, including other environmental parameters, such as (but not limited to) temperature indoors, outdoors, of a process, of a liquid. Almost any variable that is measurable by an external transducer may be introduced into the system.

The modular design provides a high degree of flexibility, so that any function desired can be mounted into a module enclosure along with a microprocessor programmed to act as a bridge, via the internal communication bus, between an external function and the master module.

In the embodiment described, up to twenty slave modules 14 (dual metering slave=two modules) can be added to a single master/display 12/16. This includes all slave module types. In the present embodiment this limitation arises from the internal data bus bandwidth and a specification that requires the polling of each slave module every second. Bandwidth may be increased if an increased number of modules are required.

The modular metering system described herein allows a number of advanced smart electricity meters to be connected together along with other elements to form a complete, scalable energy management system which can be tailored to provide a specific required solution.

Whilst endeavouring in the foregoing specification to draw attention to those features of the invention believed to be of particular importance, it should be understood that the applicant claims protection in respect of any patentable feature or combination of features referred to herein, and/or shown in the drawings, whether or not particular emphasis has been placed thereon.

1. A modular metering system comprising a master module and at least one slave module arranged to measure a parameter associated with power or energy, the master module being arranged to communicate electronically with the at least one slave module wherein each of the at least one slave module measures electricity and/or power and provides this information to the master module for processing.

2. A system according to claim 1, including a plurality of slave modules, wherein at least one of the slave modules comprises an energy meter.

3. A system according to claim 2 wherein the at least one slave module comprises an electricity meter.

4. A system according to claim 1, further comprising a communications bus through which the master module is arranged to communicate with the, or each, slave module.

5. A system according to claim 1 further comprising means for wireless communication between the master module and the, or each, slave module.

6. A system according to claim 1, further comprising a communications module arranged to facilitate communication between the master module and a remote host.

7. A system according to claim 1, wherein the slave modules are arranged for releasable physical engagement with the master module and/or other slave modules.

8. A system according to claim 7, wherein the physical engagement of modules is arranged to automatically connect a data and/or power bus between them.

9. A system according to claim 1, wherein the master module is arranged to poll the, or each, slave module.

10. A system according to claim 9, wherein the polling of the, or each, slave module is sequential.

11. A system according to claim 1, wherein the, or each, slave module includes a memory, which memory is arranged to store data including calibration data.

12. A system according to claim 1, wherein the master module includes a display, which display is arranged to present information relating to one or more slave modules.

13. A system according to claim 12, wherein the display is controllable so as to allow a user to select the slave module from which information is to be presented.

14. A system according to claim 1, wherein the master module includes a user interface which comprises an input device, such as a key pad.

15. A system according to claim 1, wherein the master module is arranged to calibrate the, or each, slave module.

16. A system according to claim 15, wherein the master module is arranged to calibrate a number of slave modules substantially simultaneously.

17. A system according to claim 1, wherein the master module further comprises power supply means for the slave modules, which power supply means comprises an auxiliary power supply for the slave modules.

18. A system according to claim 1, wherein the master module comprises electronic processing means and/or electronic memory means.

19. A system according to claim 1, wherein the, or each, slave module comprises electronic processing means and/or electronic memory means.

20. A system according to claim 1 wherein the master unit comprises a data logging means.

21. A system according to claim 1 including a plurality of electricity meters.

22. A system according to claim 1 including one or more slave modules comprising at least one three-phase electricity meter and/or three single-phase electricity meters.

23. A system according to claim 1 including one or more slave modules arranged to monitor and/or meter parameters including at least one of electricity usage, gas usage, water usage, water quality, steam usage, air quality, air usage and entry/exit by persons through a door.

24. (canceled)

25. A method of energy management, comprising measuring and/or monitoring plural parameters using meter and/or monitor slave modules connected to a master module in a system according to claim 1.

26. (canceled)
